(19) United States
(12) Patent Application Publication
(10) Pub. No.: US 2002/0180046 A1
(43) Pub. Date: Dec. 5, 2002

(54) Method for producing a flat interface for a metal-silicon contact barrier film

(75) Inventors: Yun-Yu Wang, Poughquag, NY (US); Cyril Cabral JR., Ossining, NY (US); Anthony G. Domenicucci, New Paltz, NY (US); Johnathan Faltermeier, LaGrange, NY (US); Lynne M. Gignac, Beacon, NY (US); Christian Lavoie, Ossining, NY (US); Colleen M. Snavely, Hopewell Junction, NY (US); Horatio S. Wildman, Wappingers Falls, NY (US); Kwong Hon Wong, Wappingers Falls, NY (US)

Correspondence Address: Jay H. Anderson, IBM Corporation - Zip 482, 2070 Route 52, Hopewell Junction, NY, 12533, US

(73) Assignee: INTERNATIONAL BUSINESS MACHINES CORPORATION, ARMONK, NY (US)

(21) Appl. No.: 09/874,145

(22) Filed: Jun. 5, 2001

Related U.S. Application Data
(63) Continuation-in-part of application No. 09/482,547, filed on Jan. 13, 2000, now Pat. No. 6,417,567.
Application No. 09/482,547 is a continuation-in-part of application No. 09/025,718, filed on Feb. 18, 1998, now Pat. No. 6,022,801.

(51) Int. Cl. H01L 23/48; H01L 23/52; H01L 29/40

(52) U.S. Cl. 257/754

(57) ABSTRACT

A method for forming a conductive contact having an atomically flat interface. A layer containing titanium and one of cobalt, tungsten, tantalum, or molybdenum is deposited on a silicon substrate and the resulting structure is annealed in a nitrogen-containing atmosphere at about 500° C. to about 700° C. A conductive material is deposited on top of the structure formed on anneal. A flat interface is formed that prevents diffusion of conductive materials into the underlying silicon substrate. The method can be used to form contacts for very small devices and shallow junctions, such as are required for ULSI shallow junctions.

### CROSS-REFERENCE TO RELATED APPLICATIONS

This application is a continuation-in-part of application Ser. No. 09/482,547, filed on Jan. 13, 2000, which is a continuation-in-part of application Ser. No. 09/025,718, filed on Feb. 18, 1998, now U.S. Pat. No. 6,022,801.

### TECHNICAL FIELD

The present invention relates to the formation of conductive contacts during the fabrication of semiconductor integrated circuits. More particularly, this invention relates to a method for forming an atomically flat interface that prevents diffusion of the conductive material into the underlying semiconductor layer.

### BACKGROUND OF THE INVENTION

The continuing increase in semiconductor device circuit speed and density has been accompanied both by a decrease in the vertical dimensions of devices and by a need for reliable dense wiring. The decrease in vertical dimension has produced shallower device junctions.

In the processing of integrated circuits, individual devices that are comprised of silicon are connected into circuits by subsequent metal layers. Great care must be given to the metal-to-silicon interface because the metal-silicon junction is prone to certain problems that require process attention. Two such problems are high-ohmic connections, which may electrically look like open circuits, and poisoning of the device by the contacting metal.

During formation of an interconnect, a contact hole is created in an insulating layer, typically silicon dioxide, to expose the underlying semiconductor substrate, typically a N+ region set in a P− well, or a P+ region set in a N− well. To form the interconnect, the appropriate metal is deposited in the contact hole by standard techniques. If the metal is placed in direct contact with the semiconductor substrate, the metal can diffuse into the semiconductor during subsequent processing of the device, especially at temperatures above 400° C., which are encountered during device packaging.

Diffusion produces spiking of the metal into the semiconductor. Spiking typically extends for less than about 0.5 micron into the semiconductor, and thus is not a particular problem when the device is greater than 0.5 micron thick. For high-density circuits in which the device is less than 0.5 micron thick, however, spiking can short the metal to the underlying P−well or N−well, rendering the device inoperative.

Metal silicides are typically used to provide good ohmic contact to device junctions. Titanium silicide (TiSi₂) has become the most widely used silicide for self-aligned silicide applications in the Ultra Large Scale Integration (ULSI) industry because of its low resistivity, its ability to be self-aligned, and its relatively good thermal stability. Titanium is deposited into the contact hole by standard deposition techniques. Silicidation is conducted by subsequently heating the substrate and metal to about 500° C. to 700° C.

To minimize junction leakage, the device junction must be kept below the silicide. This distance is determined by the amount of metal deposited in the contact hole, the amount of silicon consumed during heating, and the planarity of the reaction front during heating. The amount of silicon consumed is determined by the stoichiometry and crystal structure of the silicide formed as well as by the anneal time and anneal temperature. For titanium silicide, the molar ratio of metal to silicon is two to one. The planarity of the silicide reaction front is controlled by many variables, such as the cleanliness of the silicon surface before metal deposition and the reaction temperature. Typical semiconductor fabrication sequences produce non-planar, cusped reaction fronts. Junction depths could be made shallower by using a silicidation process that consumed less silicon, produced a more nearly planar reaction front, or both.

To prevent diffusion, many semiconductor fabrication sequences use a diffusion barrier between the metal and the silicon substrate. In a common process sequence, titanium nitride (TiN) is used as a barrier against attack by tungsten hexafluoride and by fluorine during the deposition of tungsten, a commonly used conductive material, by chemical vapor deposition from tungsten hexafluoride. A preferred method for forming the nitride barrier conducts the silicidation reaction in a nitrogen-containing atmosphere, such as nitrogen gas, ammonia vapor, or forming gas. Titanium nitride is formed at the same time as titanium silicide.

The topography of the resulting interface limits the usefulness of this method in the development of smaller shallow junction devices. The method involves competing reactions in a very narrow region: formation of TiO_{y}N_{z} from above and formation of TiSi₂ from below. Thus, it is difficult to control the layer thickness of the bilayer, and the layer is typically nitrogen deficient. Formation of the titanium silicide layer consumes silicon from the substrate and the layer can be cusped.

The rough interface between titanium silicides and silicon is not good for shallow junctions or small devices. The layer is an unreliable barrier against attack during the chemical vapor deposition of tungsten, which can lead to tungsten encroachment and ruin the device. Although the barrier properties of the layer can be improved by incorporating oxygen during deposition of the titanium and the subsequent anneal, the non-uniformity in thickness of the TiO_{y}N_{z} layer, which degrades its effectiveness as a barrier, remains a problem.

U.S. Pat. No. 5,567,652 issued to Nishio discloses a method in which (1) a silicon dioxide layer is formed on the surface of the silicon substrate; (2) a layer of titanium is deposited on the oxide layer; (3) a layer of cobalt is deposited on the titanium layer; and (4) the substrate is heat treated in a nitrogen-containing atmosphere. On heat treatment, the titanium reacts with the silicon dioxide to form silicon at the interface. Then, some of the cobalt migrates through the titanium to form a layer of CoSi₂ at the interface. The layer of CoSi₂ formed at the interface reflects the crystal orientation of the silicon substrate. Consequently, a very flat layer of CoSi₂ is formed at the interface.

Several additional steps are introduced into the processing sequence, however, by this method. Initially, it is necessary to form the silicon dioxide layer. Two layers of metal, a layer of titanium and a layer of cobalt, must be individually deposited instead of a single layer of metal. Following heat treatment, it is necessary to remove both the oxygen-containing titanium nitride layer formed during heat treatment and the cobalt layer before a metal can be deposited on the CoSi₂ layer. Removal of each of these layers requires a separate step.

U.S. Pat. No. 5,047,367 issued to Wei discloses a process for the formation of a titanium nitride/cobalt silicide bilayer. The bilayer is formed by (1) depositing a layer of titanium on the silicon layer; (2) depositing a layer of cobalt on the titanium layer; and (3) annealing in a nitrogen-containing atmosphere. An additional step is required, deposition of the cobalt layer, and the final temperature of the anneal is high, about 850-950° C.

Thus, a need exists for a method for forming a barrier layer and a silicide layer in which (1) formation of the silicide layer consumes less silicon than a disilicide; (2) the interface formed between the silicide layer and the silicon substrate is a flat interface, preferably an atomically flat interface; and (3) the barrier layer is uniform in thickness. In addition, the method should be readily integratable into the procedures currently used to form semiconductor devices and, preferably, does not introduce additional processing steps.

### SUMMARY OF THE INVENTION

In accordance with the present invention, a method is provided for forming a semiconductor device with electrical interconnections that have low contact resistance and for forming a barrier layer that prevents undesired diffusion into the silicon substrate.

According to a first embodiment of the invention, this method comprises:

a) depositing a layer consisting essentially of titanium and an element selected from the group consisting of cobalt, tungsten, tantalum, and molybdenum on a silicon substrate, in which the amount of the element selected from the group consisting of cobalt, tungsten, tantalum, and molybdenum present in the layer does not exceed 20 atomic percent of the total amount of the element and titanium present in the layer;

b) annealing the substrate and the layer in a nitrogen-containing atmosphere at about 500° C. to about 700° C.; and

c) depositing a conductive material on the layer.

The method produces an atomically flat interface between the suicides formed during processing and the silicon substrate. The flat interface is critical for contacts for very small devices and shallow junctions, such as are required for ULSI shallow junctions. The uniform TiO_{y}N_{z} (titanium oxynitride, tioxynitride) layer formed by this method is a good barrier against attack by tungsten hexafluoride and fluorine during the chemical vapor deposition of tungsten.

Although not intending to be bound by any theory or explanation, it is believed that the cobalt in the titanium-cobalt alloy layer plays two roles during the annealing. First, the cobalt migrates to the silicon surface and slows formation of the silicide. Second, because of differences in both atomic radius and electronic structure between the cobalt and titanium atoms, each of these atoms bonds differently to silicon. This difference in bonding to silicon destroys the long-range spatial and electronic periodicity of the silicide crystal and allows formation of highly disordered nano-crystalline or amorphous silicide. The highly disordered silicide forms, in turn, an atomically flat interface between silicon and the silicide. Highly disordered silicide also causes formation of a uniformly thick TiO_{y}N_{z} layer. Thus, a much more reliable barrier against attack of the silicon by metal or fluorine is created. In addition, a better-controlled silicide interface, which is more suitable for contact in shallow junction applications, is formed.

Unlike cobalt, the elements tungsten, tantalum, and molybdenum have atomic diameters that are similar to that of titanium. However, they have different electronic structures. Because of these differences in electronic structure, each of these atoms bonds differently to silicon, destroying the long-range spatial and electronic periodicity of the silicide crystal. As in the case of cobalt, this forms a highly disordered nano-crystalline or amorphous silicide.

According to a second embodiment of the invention, a method is provided which comprises the following steps:

a) depositing a multilayer structure on a semiconductor substrate, the multilayer structure including a first layer comprising titanium and in contact with the substrate, a second layer overlying the first layer and comprising an element selected from the group consisting of cobalt, tungsten, tantalum, and molybdenum, and a third layer comprising titanium overlying the second layer, in which the amount of the element selected from the group consisting of cobalt, tungsten, tantalum, and molybdenum present in the structure does not exceed 20 atomic percent of the total amount of the element and titanium present in the structure; and

b) annealing the substrate and the layer in a nitrogen-containing atmosphere at about 500° C. to about 700° C.

In this embodiment, the thickness of the multilayer structure is about 9 nm to about 170 nm thick, and is preferably about 16 nm thick. The structure and substrate may advantageously be annealed at about 600° C. for about 0.5 hour.

In accordance with an additional embodiment of the invention, a contact is provided in which the interface between the silicon substrate and its adjacent layer is atomically flat. In still another embodiment, the invention is a contact formed by the method of the invention. It is to be understood that both the foregoing general description and the following detailed description are exemplary, but are not restrictive, of the invention.

### BRIEF DESCRIPTION OF THE DRAWING

The invention is best understood from the following detailed description when read in connection with the accompanying drawing. It is emphasized that, according to common practice, the various features of the drawing are not to scale. On the contrary, the dimensions of the various features are arbitrarily expanded or reduced for clarity. Included in the drawing are the following figures:

FIG. 1 is a cross-section of a silicon substrate with a titanium-cobalt alloy layer formed on the substrate, in accordance with the first embodiment of the invention;

FIG. 2a is a cross-section of the multi-layer structure formed on anneal of the structure shown in FIG. 1;

FIG. 2b is a cross-section of a contact formed by a method in accordance with the first embodiment of the invention;

FIG. 3 shows a transmission electron microscopy (TEM) micrograph of a cross-section of a cobalt-containing, multi-layer structure formed on anneal;

FIG. 4 shows at higher magnification the TEM micrograph of the cross-section of the multi-layer structure formed on anneal;

FIG. 5 shows a cross-section of a tungsten-containing, multi-layer structure formed on anneal;

FIG. 6 shows a cross-section of a tantalum-containing, multi-layer structure formed on anneal;

FIG. 7 shows a cross-section of a molybdenum-containing, multi-layer structure formed on anneal;

FIG. 8 is a cross-section of a silicon substrate with a multilayer structure formed on the substrate, in accordance with the second embodiment of the invention;

FIG. 9 is a cross-section of the multi-layer structure formed on anneal of the structure shown in FIG. 8;

FIG. 10 is a cross-section of a contact formed by a method in accordance with the second embodiment of the invention; and

FIG. 11 shows a transmission electron microscopy (TEM) micrograph of a cross-section of a cobalt-containing, multi-layer structure formed on anneal, in accordance with the second embodiment of the invention.

FIG. 12 is a graph showing electrical contact resistance data for samples prepared in accordance with the second embodiment of the invention, in comparision with data from samples prepared in accordance with a conventional process.

### DESCRIPTION OF THE PREFERRED EMBODIMENTS

The present invention includes a process for forming an atomically flat interface between a silicon substrate and a (Ti,M)Siₓ/TiO_{y}N_{z} layer, in which M is selected from the group consisting of cobalt (Co), tungsten (W), tantalum (Ta), and molybdenum (Mo), for use in self-aligned silicide technology and as a contact via fill. The layer serves as a barrier against attack on the silicon substrate during subsequent processing steps, such as attack by tungsten hexafluoride and fluorine during subsequent chemical vapor deposition of tungsten from tungsten hexafluoride.

The invention will now be described by reference to the accompanying figures. Throughout the specification, similar reference characters refer to similar elements in all of the figures. Although certain aspects of the invention will be described with respect to the use of cobalt, except where indicted the description also applies to the use of tungsten, to the use of tantalum, and to the use of molybdenum in place of cobalt.

### FIRST EMBODIMENT

### Alloy Layer Deposition on Substrate

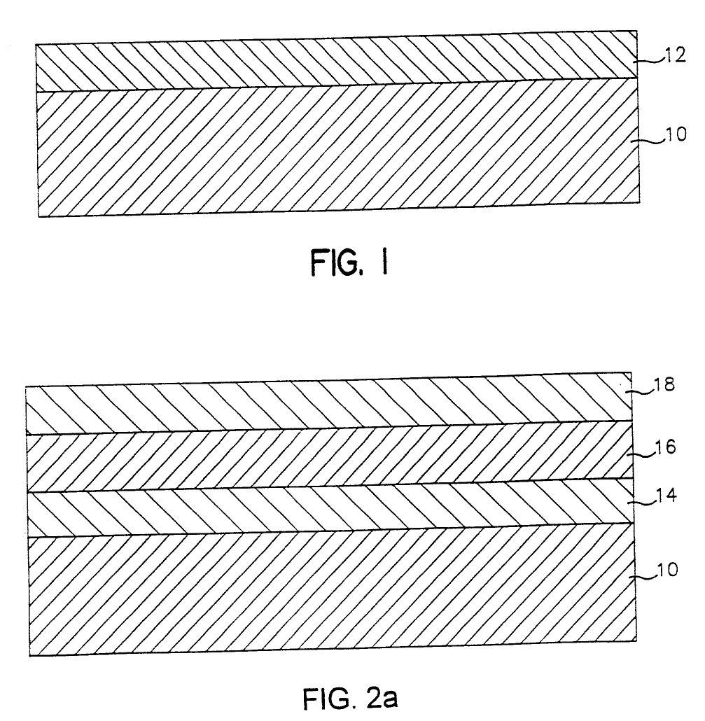

Referring to FIG. 1, silicon substrate 10 may be either mono-crystalline or poly-crystalline silicon. Using methods well known to those skilled in the art, such as are described, for example, by S. A. Campbell in The Science and Engineering of Microelectronic Fabrication, Oxford University Press, New York, 1996, the silicon substrate can be provided, for example, by formation of a contact hole, or via, in the dielectric layer over the region of a silicon substrate at which a connection is desired. Typically, the contact hole is formed over an N+ region set in a P−well or a P+ region set in an N−well.

A titanium-cobalt alloy layer 12 is deposited on the surface of silicon substrate 10 by any one of several techniques known in the art. Deposition techniques include, for example, physical vapor deposition, chemical vapor deposition, plasma-enhanced chemical vapor deposition, flash evaporation, sputtering, electron beam evaporation, and ion-assisted deposition. The apparatus and techniques for vacuum deposition are well known to those skilled in the art.

The titanium and the cobalt may be deposited from different sources or from a source of titanium that also contains cobalt. For example, if the layer is deposited by sputtering, a sputtering target of titanium and cobalt is prepared such that a titanium layer containing the desired atomic percentage of cobalt is deposited on the silicon substrate. Alternatively, the layer can be deposited by co-sputtering titanium and cobalt such that a titanium film containing the desired atomic percentage of cobalt is deposited on the silicon substrate. When the physical vapor deposition process of evaporation is used, the titanium and cobalt are deposited from two different sources at appropriate rates to achieve the desired atomic percentage of cobalt. Other processes known in the art may also be used to deposit titanium-cobalt alloy layer 12.

The amount of cobalt present in titanium-cobalt alloy layer 12 should not exceed about 20 atomic percent of the total amount of cobalt and titanium present in the layer, typically about 0.1 to about 20 atomic percent cobalt. Titanium-cobalt alloy layer 12 preferably contains about 1 to about 10 atomic percent cobalt, more preferably about 3 to about 7 atomic percent cobalt, and most preferably about 5 atomic percent cobalt.

Titanium-cobalt alloy layer 12 typically has a thickness of about 5 nm to about 100 nm, preferably about 5 nm to about 30 nm, more preferably about 5 nm to about 20 nm. Most preferably, titanium-cobalt alloy layer 12 is about 6 nm to about 10 nm thick.

Following deposition of titanium-cobalt alloy layer 12, substrate 10 and layer 12 are annealed in a nitrogen-containing atmosphere, such as ammonia vapor, forming gas (a mixture of nitrogen and hydrogen), or nitrogen gas. The time and temperature are selected to ensure formation of the (Ti,Co)Siₓ and TiO_{y}N_{z} layers. The annealing step may be conducted at about 500° C. to about 700° C. for about 0.5 hour to about 2 hours. Above about 700° C., agglomeration of the (Ti,Co)Siₓ is observed. Preferably, the annealing step is conducted at about 550° C. for about 0.5 hour. The anneal may be done by methods well known to those skilled in the art, such as in a conventional annealing furnace or by rapid thermal anneal.

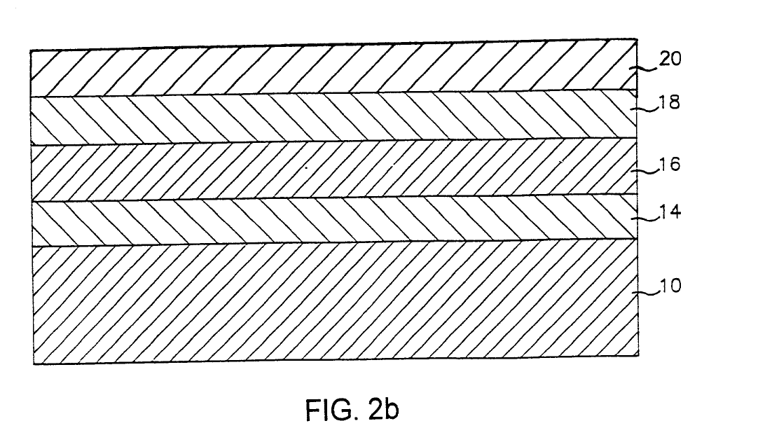

FIG. 2a shows the multi-layer structure formed on anneal. The multi-layer structure consists of silicon substrate 10, a cobalt silicide (CoSi_{w}) layer 14, a highly disordered silicide ((Ti,Co)Siₓ) layer 16, and a titanium oxynitride or tioxynitride (TiO_{y}N_{z}) layer 18.

During the initial stages of anneal, the titanium present in titanium-cobalt alloy layer 12 removes any silicon dioxide present on the surface of silicon substrate 10. Generally, this oxide layer is only about 0.1 to 0.5 nm (1 to 5 Å) thick. Silicon dioxide dissolves into the titanium. Subsequently, the oxygen is rejected into the TiO_{y}N_{z} layer 18 by the growing silicide layer.

During anneal, cobalt in the (titanium-cobalt) alloy migrates to the silicon-(titanium-cobalt) alloy boundary while silicon and the (titanium-cobalt) alloy form alloyed silicide. Within (Ti,Co)Siₓ layer 16, cobalt segregates toward the interface between silicon and the alloyed silicide layer and forms CoSi_{w} layer 14 at the boundary between the silicon and the alloyed silicide layer. CoSi_{w} layer 14 is believed to be about a monolayer thick. CoSi_{w} layer 14 has been detected by TEM analysis, nano-probe electron energy loss spectroscopy, and energy dispersive X-ray analysis.

TEM analysis has detected formation of an analogous tungsten silicide layer when tungsten is used in place of cobalt. The tungsten silicide layer is about a monolayer thick and is atomically flat. Although analogous silicide layers may be formed when tantalum or molybdenum is used in place of cobalt, formation of these layers has not been detected by TEM analysis.

The cobalt remaining in the silicide layer destroys the long-range spatial and electronic periodicity of the silicide crystal, producing a highly disordered layer of silicide. “Highly disordered” means that (Ti,Co)Siₓ layer 16 is either nano-crystalline or amorphous. As is well known to those skilled in the art, “nano-crystalline” means that there is some localized, short range order in the layer, typically about a few nanometers, while “amorphous” means that there is no order in the layer greater than a few A. Highly disordered (Ti,Co)Siₓ layer 16 causes formation of an atomically flat interface between silicon substrate 10 and highly disordered (Ti,Co)Siₓ layer 16.

Due to segregation of the cobalt during anneal, the amount of cobalt in highly disordered (Ti,Co)Siₓ layer 16 is greater than the amount present in titanium-cobalt layer 12. The amount of cobalt in highly disordered (Ti,Co)Siₓ layer 16 is typically about 0.2 to about 35 atomic percent, preferably about 2 to about 15 atomic percent, more preferably about 5 to about 10 atomic percent, and most preferably about 8 atomic percent, based on the total amount of cobalt and titanium present in (Ti,Co)Siₓ layer 16. If the amount of cobalt in titanium-cobalt alloy layer 12 is about 5 atomic percent of the total amount of cobalt and titanium present in titanium-cobalt layer 12, the amount of cobalt in (Ti,Co)Siₓ layer 16 is typically about 8 atomic percent of the total amount of cobalt and titanium present in (Ti,Co)Siₓ layer 16.

Highly disordered (Ti,Co)Siₓ layer 16 is typically slightly more than half as thick as titanium-cobalt alloy layer 12. (Ti,Co)Siₓ layer 16 typically has a thickness of about 3 nm to about 60 nm, preferably about 3 nm to about 20 nm, more preferably about 3 nm to about 12 nm. Most preferably, (Ti,Co)Siₓ layer 16 is about 4 nm to about 7 nm thick. When titanium-cobalt alloy layer 12 is about 9 nm thick, highly disordered (Ti,Co)Siₓ layer 16 is typically about 5 nm thick. Although the exact value of x depends on the conditions under which (Ti,Co)Siₓ layer 16 is formed (i.e., the amount of cobalt in titanium-cobalt alloy layer 12, the thickness of titanium-cobalt alloy layer 12, the anneal temperature, and the like), x has a value between one and two.

The titanium in titanium-cobalt alloy layer 12 reacts with nitrogen in the nitrogen-containing atmosphere and the oxygen that was present on the surface of titanium-cobalt alloy layer 12 to form TiO_{y}N_{z} layer 18. No detectable cobalt remains in TiO_{y}N_{z} layer 18. Due to the atomically flat interface between silicon substrate 10 and (Ti,Co)Siₓ layer 16, TiO_{y}N_{z} layer 18 is very uniform in thickness, which makes it a more reliable barrier against attack by metals and by fluorine during subsequent processing steps.

TiO_{y}N_{z} layer 18 is typically slightly less than half as thick as titanium-cobalt alloy layer 12. TiO_{y}N_{z} layer 18 typically has a thickness of about 2 nm to about 40 nm, preferably about 2 nm to about 15 nm, more preferably about 2 nm to about 8 nm. Most preferably, TiO_{y}N_{z} layer 18 is about 3 nm to about 6 nm thick. When titanium-cobalt alloy layer 12 is about 9 nm thick, TiO_{y} N_{z} layer 18 is typically about 4 nm thick.

The values of y and z depend on the reaction conditions and typically vary across the cross-section of TiO_{y}N_{z} layer 18. Typically, the amount of oxygen near the with highly disordered (Ti,Co)Siₓ layer 16 is greater than the amount of oxygen at the surface, and the amount of nitrogen is greater at the surface than the amount of nitrogen near the interface with (Ti,Co)Siₓ layer 16.

After anneal, it is unnecessary to remove any of the layers formed on anneal. A conductive material can be deposited directly on top of the interface by methods well known to those skilled in the art. Typical conductive materials include, for example, tungsten, aluminum, copper, gold, tantalum, aluminum-copper alloy, and aluminum-silicon-copper alloy. A preferred conductive material is tungsten. Tungsten may be deposited by chemical vapor deposition of tungsten hexafluoride (WF₆). FIG. 2b shows conductive material 20 over TiO_{y}N_{z} layer 18.

### SECOND EMBODIMENT

### Multilayer Deposition on Substrate

In a second embodiment of the invention, a multilayer structure is deposited on the substrate 10, instead of an alloy layer. As shown in FIG. 8, this structure includes three distinct layers 421-423. Layer 421 is of titanium and typically has a thickness of about 4 nm to about 40 nm, preferably about 7 nm. Layer 422 is of a metal M selected from the group consisting of Co, W, Ta and Mo, and typically has a thickness of about 1 nm to about 10 nm, preferably about 2 nm. Layer 423 is of titanium and typically has a thickness of about 4 nm to about 120 nm, preferably about 7 nm.

In contrast to the alloy deposition in the first embodiment, layers 421-423 are deposited in separate processes. This is preferably done in a vacuum deposition apparatus of the “cluster tool” type, in which separate processing chambers share a loadlock chamber so that the substrate may be moved between chambers without being exposed to atmosphere. For example, deposition of a Ti/Co/Ti three-layer structure may be performed in a two-chamber sputtering tool, where one chamber has a Ti sputtering target and the other chamber has a Co sputtering target. As noted above, a variety of vacuum deposition techniques may be used.

As in the first embodiment, the amount of metal M should not exceed about 20 atomic percent of the total amount of metal (Ti and M combined) in the three layers Preferably, the amount of metal M is in the range of about 2 atomic percent to 15 atomic percent of the total.

Following deposition of layers 421-423, substrate 10 and layers 421-423 are annealed in a nitrogen-containing atmosphere, such as ammonia vapor, forming gas (a mixture of nitrogen and hydrogen), or nitrogen gas. As in the first embodiment, the time and temperature are selected to ensure formation of a highly disordered (Ti, M)Siₓ layer and a TiO_{y}N_{z} layer. The annealing step may be conducted at about 500° C. to about 700° C. for about 0.5 hour to about 2 hours. It has been found that, when Co is used in layer 422, agglomeration of (Ti, Co)Siₓ is less likely to occur than in the first embodiment. Accordingly, the annealing step may be performed at a higher temperature. Preferably, in this embodiment the annealing step is conducted at about 600° C. for about 0.5 hour. As noted above, the anneal may be done by methods well known to those skilled in the art, such as in a conventional annealing furnace or by rapid thermal anneal.

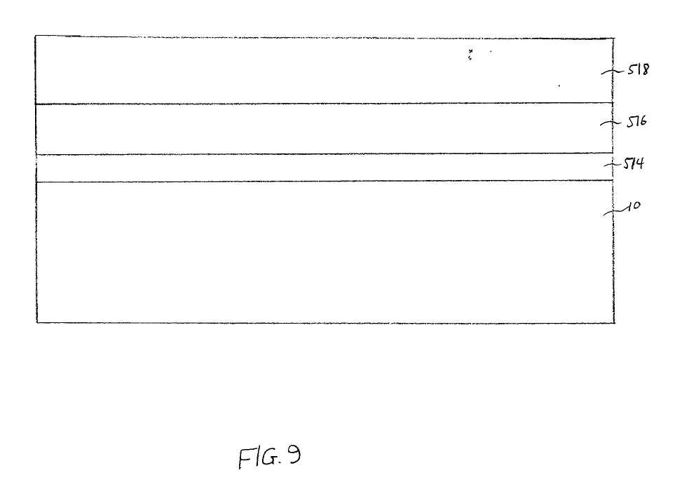

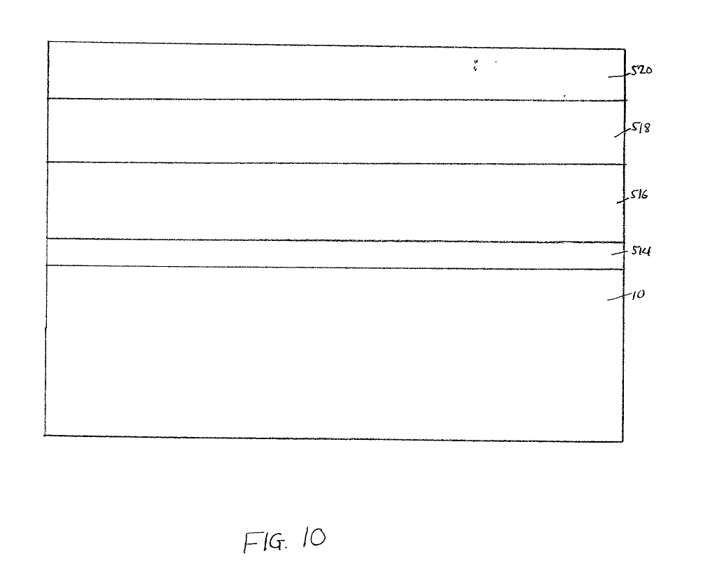

FIG. 9 shows the multi-layer structure formed on anneal. The multi-layer structure includes silicon substrate 10; a metal silicide layer 514, e.g. cobalt silicide (CoSi_{w}); a highly disordered silicide layer 516, e.g. (Ti,Co)Siₓ; and a titanium oxynitride or tioxynitride (TiO_{y}N_{z}) layer 518.

During the initial stages of anneal, the titanium present in layer 421 removes any silicon dioxide present on the surface of silicon substrate 10; the silicon dioxide dissolves into the titanium. Subsequently, the oxygen is rejected into the TiO_{y}N_{z} layer 518 by the growing silicide layer. The metal M (e.g. cobalt) in layer 422 migrates to the silicon-titanium boundary while Si, Ti and M form an alloyed silicide. Within the (Ti, M)Siₓ layer 516, the metal segregates toward the interface between silicon and the alloyed silicide layer and forms silicide layer 514 (e.g. CoSi_{w}) at the boundary between the silicon and the alloyed silicide layer.

As noted above, the metal M remaining in the silicide layer destroys the long-range spatial and electronic periodicity of the silicide crystal, producing a highly disordered (that is, either nano-crystalline or amorphous) layer 516 of silicide. This results in formation of an atomically flat interface between silicon substrate 10 and highly disordered layer 516.

When a three-layer structure of Ti/Co/Ti with the above-described thicknesses is deposited, a highly disordered (Ti,Co)Siₓ layer 516 is formed after anneal which typically has a thickness of about 3 nm to about 60 nm, preferably about 3 nm to about 20 nm, more preferably about 3 nm to about 12 nm. Most preferably, (Ti,Co)Siₓ layer 516 is about 4 nm to about 7 nm thick. Although the exact value of x depends on the conditions under which (Ti,Co)Siₓ layer 516 is formed (i.e., the amount of cobalt in the three-layer structure 421-423, the anneal temperature, and the like), x has a value between one and two.

The titanium in layer 423 reacts with nitrogen in the nitrogen-containing atmosphere and the oxygen in the dissolved silicon dioxide to form TiO_{y}N_{z} layer 518. No detectable cobalt remains in TiO_{y}N_{z} layer 518. Due to the atomically flat interface between silicon substrate 10 and (Ti,Co)Siₓ layer 516, TiO_{y}Nₓ layer 518 is very uniform in thickness, which makes it a reliable barrier against attack by metals and by fluorine during subsequent processing steps.

TiO_{y}N_{z} layer 518 typically has a thickness of about 2 nm to about 40 nm, preferably about 2 nm to about 15 nm, more preferably about 2 nm to about 8 nm. Most preferably, TiO_{y}N_{z} layer 518 is about 3 nm to about 6 nm thick The values of y and z depend on the reaction conditions and typically vary across the cross-section of TiO_{y}N_{z} layer 518. Typically, the amount of oxygen near the interface with highly disordered (Ti,Co)Siₓ layer 516 is greater than the amount of oxygen at the surface, and the amount of nitrogen is greater at the surface than the amount of nitrogen near the interface with (Ti,Co)Siₓ layer 516.

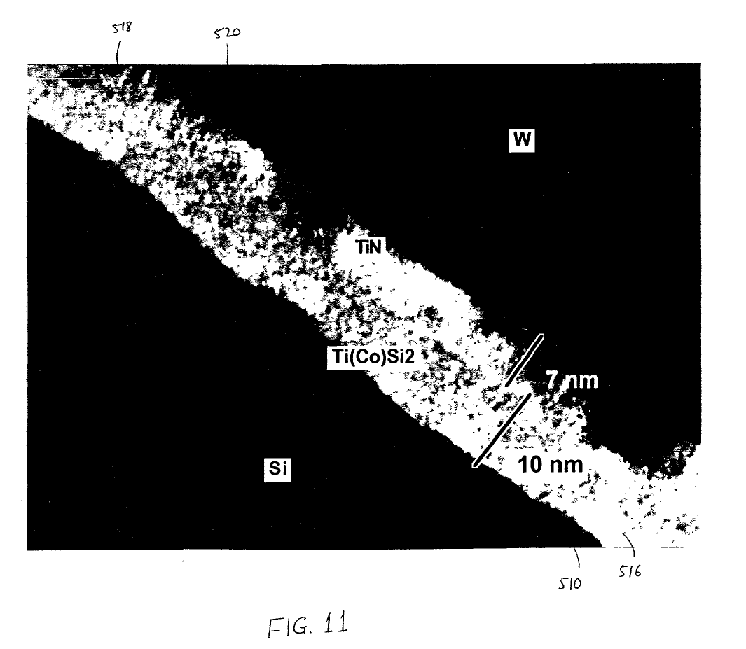

As in the first embodiment, a conductive material may be deposited directly on top of TiO_{y}N_{z} layer 518 by methods well known to those skilled in the art. Typical conductive materials include, for example, tungsten, aluminum, copper, gold, tantalum, aluminum-copper alloy, and aluminum-silicon-copper alloy. In addition, a multilayer structure (e.g. layers of Al and Cu) may be deposited on top of layer 518. A preferred conductive material is tungsten. Tungsten may be deposited by chemical vapor deposition of tungsten hexafluoride (WF₆). FIG. 10 shows conductive material 520 deposited over layer 518.

Compared with the alloy deposition process of the first embodiment, the multilayer deposition process of the second embodiment may represent increased process complexity. However, the process of the second embodiment is preferable when it is particularly desired to avoid agglomeration of the silicide layer during the anneal.

Industrial Applicability

The invention can be used in the manufacture of semiconductor devices, which are used in, for example, digital computers. The method produces an atomically flat interface for a tungsten barrier plug film, which provides an improved plug for ULSI shallow junctions. The junction can be used to form the source and drain elements for semiconductor devices. The method may be readily integrated into present semiconductor fabrication techniques that currently use titanium silicide layers formed from undoped titanium.

The flat, smooth interface between the silicide and the substrate also results in lower leakage currents in the device. This advantage is critical for low-power-consumption applications such as hand-held computers and digital cell phones.

The advantageous properties of this invention can be observed by reference to the following examples, which illustrate but do not limit the invention.

### EXAMPLE

### Example 1

This example describes preparation of an interface in accordance with the first embodiment of the invention. Silicon substrate 10 was undoped monocrystalline silicon about 0.7 mm thick. Doped silicon and polycrystalline silicon, typically a N+ region set in a P−well or a P+ region set in an N−well, can also be used. A cobalt-containing titanium layer was deposited on the silicon substrate by co-evaporation. The layer contained 5 atomic percent cobalt and was 10 nm thick. The substrate was annealed at 550° C. for 0.5 hour in nitrogen gas. An anneal was conducted in a conventional annealing furnace.

The resulting structure contains TiO_{y}N_{z} layer 18, highly disordered (Ti,Co)Siₓ layer 16, CoSi_{w} layer 14, and silicon substrate 10. The structure was analyzed by TEM imaging, nano-probe analytical TEM with energy dispersive X-ray and electron energy loss spectroscopy, Auger, and X-ray diffraction.

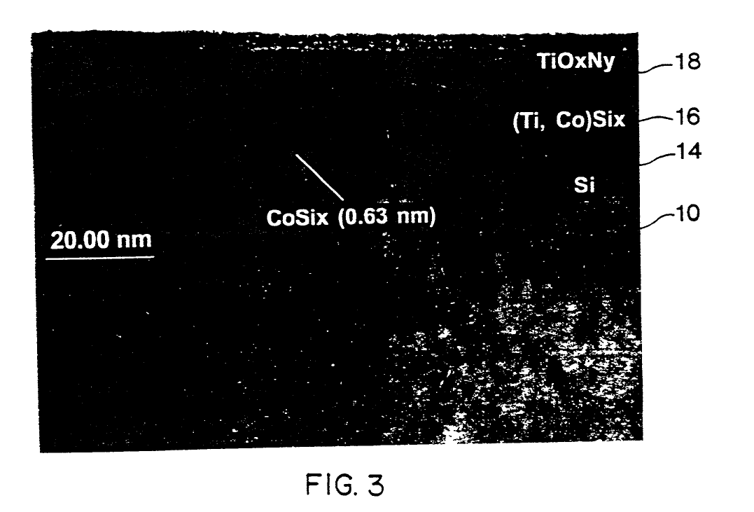

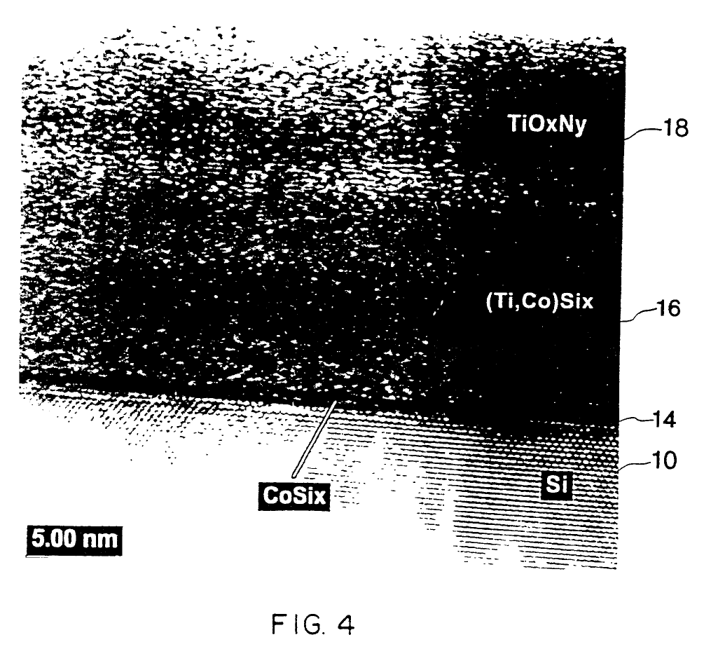

TEM analysis of a cross-section of the multi-layer structure formed on anneal is shown in FIG. 3 and FIG. 4. Visible are silicon substrate 10, CoSi_{w} layer 14, highly disordered (Ti,Co)Siₓ layer 16, and TiO_{y}N_{z} layer 18. As shown in the figures, CoSi_{w} layer 14 is about a monolayer thick, having a thickness of about 0.63 nm (6.3 Å) and is atomically flat. The flat interface between silicon substrate 10 and CoSiw layer 14 and the flat interface between CoSi_{w} layer 14 and highly disordered (Ti,Co)Siₓ layer 16 are also visible.

CoSi_{w} layer 14 can also be detected by nano-probe electron energy loss spectroscopy and energy dispersive x-ray analysis.

### Example 2

The procedure of Example 1 was repeated using tungsten in place of cobalt. The resulting structure contains a TiO_{y}N_{z} layer 118, a highly disordered (Ti,W)Si_{w} layer 116, a WSi_{w} layer 114, and a silicon substrate 110.

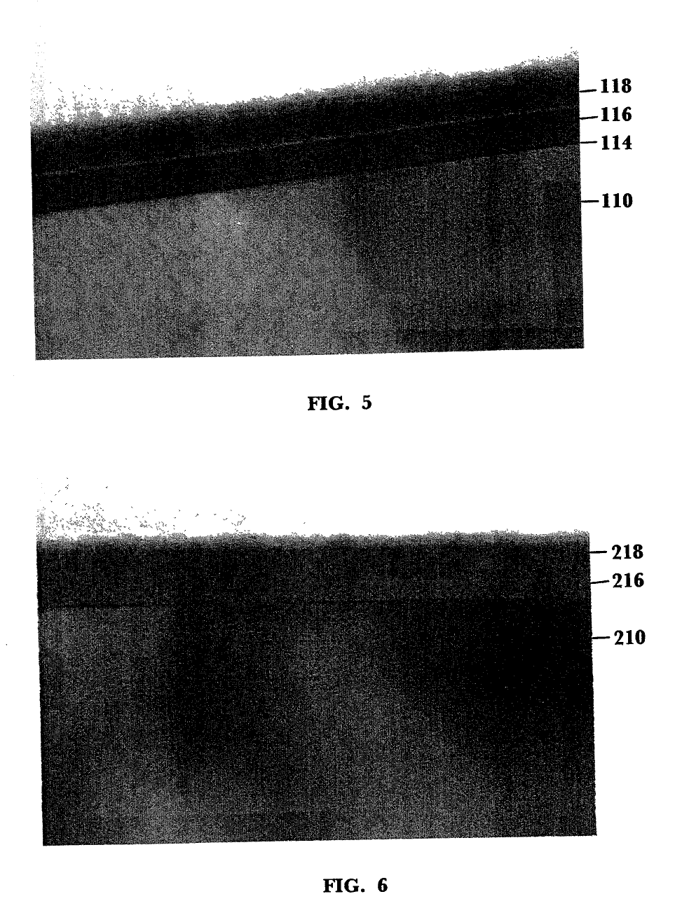

TEM analysis of a cross-section of the multi-layer structure formed on anneal is shown in FIG. 5. Visible are silicon substrate 110, WSi_{w} layer 114, highly disordered (Ti,W)Siₓ layer 116, and TiO_{y}N_{z} layer 118. As shown in FIG. 5, WSi_{w} layer 114 is about a monolayer thick, having a thickness of about 0.7-1.0 nm (7-10 Å) and is atomically flat. The flat interface between silicon substrate 110 and WSi_{w} layer 114 and the flat interface between WSi_{w} layer 114 and highly disordered (Ti,W)Siₓ layer 116 are also visible.

### Example 3

The procedure of Example 1 was repeated using tantalum in place of cobalt. The resulting structure contains a TiO_{y}N_{z} layer 218, a highly disordered (Ti,Ta)Siₓ layer 216, and a silicon substrate 210.

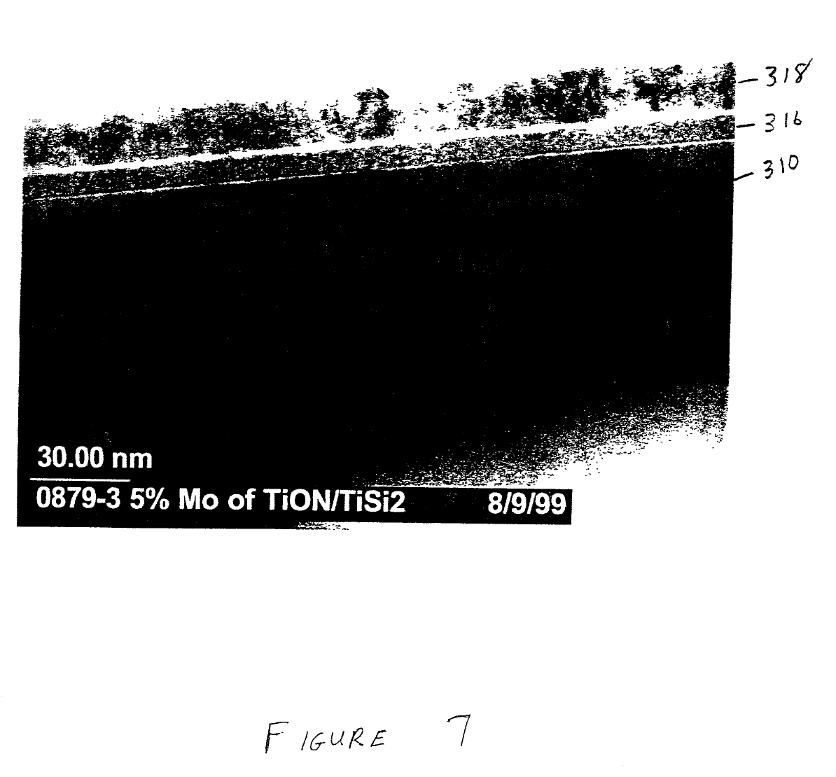

TEM analysis of a cross-section of the multi-layer structure formed on anneal is shown in FIG. 6. Visible are silicon substrate 210, highly disordered (Ti,Ta)Siₓ layer 216, and TiO_{y}N_{z} layer 218. The flat interface between silicon substrate 210 and highly disordered (Ti,Ta)Siₓ layer 216 is also visible.

### Example 4

The procedure of Example 1 was repeated using molybdenum in place of cobalt. The resulting structure contains a TiO_{y}N_{z} layer 318, a highly disordered (Ti,Mo)Siₓ layer 316, and a silicon substrate 310.

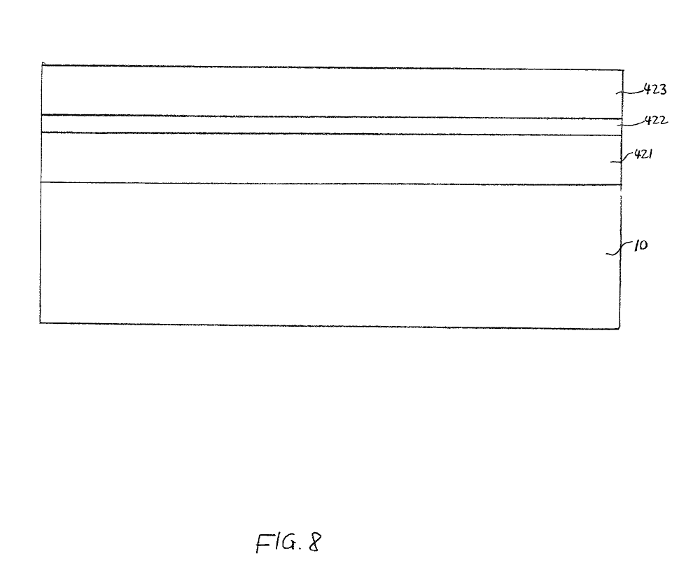

TEM analysis of a cross-section of the multi-layer structure formed on anneal is shown in FIG. 7. Visible are silicon substrate 310, highly disordered (Ti,Mo)Siₓ layer 316, and TiO_{y}N_{z} layer 318. The flat interface between silicon substrate 310 and highly disordered (Ti,Mo)Siₓ layer 316 is also visible.

### Example 5

This example describes preparation of an interface in accordance with the second embodiment of the invention. Silicon substrate 10 was undoped monocrystalline silicon about 0.7 mm thick. Distinct layers of Ti, Co and Ti were deposited on the substrate by evaporation. The first layer (Ti), deposited on the substrate 10, was 15 nm thick; the second layer (Co) was 4 nm thick; and the third layer (Ti ) was 15 nm thick. The substrate was annealed at 600° C. for 0.5 hour in nitrogen gas. The anneal was conducted in a conventional annealing furnace. The resulting structure contains a TiO_{y}N_{z} layer 518, a highly disordered (Ti,Co)Siₓ layer 516, and a silicon substrate 510.

TEM analysis of a cross-section of the multi-layer structure formed on anneal is shown in FIG. 11. Visible are silicon substrate 510, highly disordered (Ti,Co)Siₓ layer 516, TiO_{y}N_{z} layer 518, and tungsten layer 520. The flat interface between silicon substrate 510 and highly disordered (Ti,Co)Siₓ layer 516 is also visible. As shown in FIG. 11, the thickness of layer 516 is 10 nm and the thickness of layer 518 is 7 nm.

Electrical Test Data

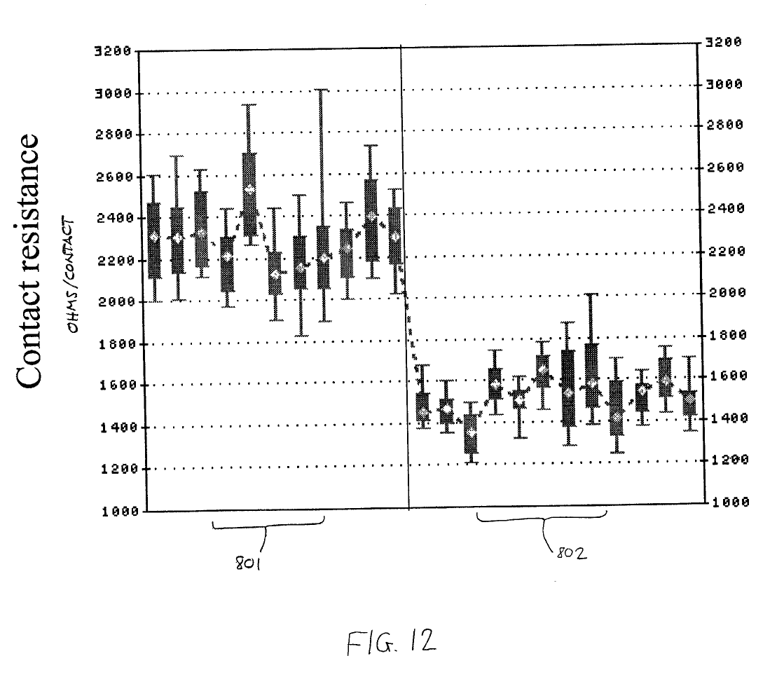

A graph of contact resistance data, showing an advantage of the present invention, appears in FIG. 12. Data points 801 show contact resistances (in units of ohms per contact) in samples prepared using a conventional process, in which a layer of Ti was deposited on a Si substrate using an ionized metal plasma. The resulting silicide formed on the substrate (TiSi₂) is crystalline and may exhibit agglomeration (and thus high contact resistance). In contrast, data points 802 show contact resistances in samples prepared according to the second embodiment of the present invention, with a three-layer Ti/Co/Ti structure deposited on the substrate. In these samples, a highly disordered (Ti,Co)Siₓ layer was formed on the substrate; as discussed above, agglomeration is less likely than with the conventional process, so that the contact resistances are significantly lower. In FIG. 12, a diamond shape denotes the median resistance value for the sample; the wide bars represent the data spread between the 25^{th} and the 75^{th} percentile; and the narrow bars represent the data spread between the 10^{th} and 90^{th} percentile.

It should be noted that an amorphous or highly disordered silicide generally has a higher sheet resistance than a crystalline silicide. However, as shown in FIG. 12, formation of a highly disordered silicide permits formation of contacts with lower contact resistance. This is an unexpected result in view of the known sheet resistance data.

Although illustrated and described above with reference to certain specific embodiments, the present invention is nevertheless not intended to be limited to the details shown. Rather, various modifications may be made in the details within the scope and range of equivalents of the claims and without departing from the spirit of the invention.

1. A method comprising:
a) depositing a multilayer structure on a semiconductor substrate, the multilayer structure including a first layer comprising titanium and in contact with the substrate, a second layer overlying the first layer and comprising an element selected from the group consisting of cobalt, tungsten, tantalum, and molybdenum, and a third layer comprising titanium overlying the second layer, in which the amount of the element does not exceed 20 atomic percent of the total amount of the element and titanium present in the multilayer structure, and
b) annealing the substrate and the structure in a nitrogen-containing atmosphere at about 500° C. to about 700° C.

2. The method of claim 1 in which the multilayer structure is about 9 nm to about 170 nm thick.

3. The method of claim 2 in which the amount of the element present in the structure is about 1 to about 10 atomic percent of the total amount of the element and titanium present in the structure.

4. The method of claim 3 in which the structure is about 9 nm to about 20 nm thick and the amount of the element present in the structure is about 3 to about 7 atomic percent of the total amount of the element and titanium present in the structure.

5. The method of claim 4 in which the structure is about 16 nm thick, the amount of the element present in the structure is about 5 atomic percent of the total amount of the element and titanium present in the structure, and the annealing is conducted at about 600° C. for about 0.5 to 2 hours.

6. The method of claim 5 in which the element is cobalt.

7. The method of claim 5 in which the element is tungsten.

8. The method of claim 5 in which the element is tantalum.

9. The method of claim 5 in which the element is molybdenum.

10. The method of claim 1 additionally comprising, after step (b), the step (c) of depositing a conductive material on the structure.

11. The method of claim 10 in which the multilayer structure is about 9 nm to about 170 nm thick.

12. The method of claim 11 in which the amount of the element present in the structure is about 1 to about 10 atomic percent of the total amount of the element and titanium present in the structure.

13. The method of claim 12 in which the depositing step is performed using a vacuum deposition technique.

14. The method of claim 10 in which the structure is about 9 nm to about 20 nm thick and the amount of the element present in the structure is about 3 to about 7 atomic percent of the total amount of the element and titanium present in the structure.

15. The method of claim 10 in which the conductive material is tungsten.

16. The method of claim 15 in which the structure is about 9 nm to about 170 nm thick and the amount of the element present in the structure is about 1 to about 10 atomic percent of the total amount of the element and titanium present in the structure.

17. The method of claim 16 in which the structure is about 5 nm to about 20 nm thick and the amount of the element present in the structure is about 3 to about 7 atomic percent of the total amount of the element and titanium present in the structure.

18. The method of claim 17 in which the structure is about 16 nm thick, the amount of the element present in the structure is about 5 atomic percent of the total amount of the element and titanium present in the structure, and the annealing is conducted at about 600° C. for about 0.5 to 2 hours.

19. A contact prepared by the method of claim 10.

20. The contact of claim 19 in which the conductive material is tungsten.

21. The contact of claim 20 in which the multilayer structure is about 9 nm to about 170 nm thick and the amount of the element present in the structure is about 1 to about 10 atomic percent of the total amount of the element and titanium present in the structure.

22. The contact of claim 21 in which the structure is about 16 nm thick; the amount of the element present in the structure is about 5 atomic percent of the total amount of the element and titanium present in the structure; and the annealing is conducted at about 600° C. for about 0.5 to 2 hours.

23. The contact of claim 22 in which the element is cobalt.

24. The contact of claim 22 in which the element is tungsten.

25. The contact of claim 22 in which the element is tantalum.

26. The contact of claim 22 in which the element is molybdenum.
